(19) United States
(12) Patent Application Publication
(10) Pub. No.: US 2016/0192515 A1
(43) Pub. Date: Jun. 30, 2016

(54) CIRCUIT BOARD ASSEMBLY AND ASSEMBLING METHOD THEREOF

(71) Applicant: DELTA ELECTRONICS, INC., Taoyuan Hsien (TW)

(72) Inventors: Hung-Chuan Chen, Taoyuan Hsien (TW); Sheng-Yao Jiang, Dongguan (CN); Kuo-Hua Lin, Taoyuan Hsien (TW)

(21) Appl. No.: 14/802,308

(22) Filed: Jul. 17, 2015

(30) Foreign Application Priority Data
Dec. 25, 2014 (CN) 201410826040.1

(51) Int. Cl. H05K 5/00; H05K 7/14; H05K 5/02; H05K 1/14; H01R 12/73; H01R 43/20

(52) U.S. Cl. CPC H05K 5/0065; H01R 12/73; H01R 43/205; H05K 5/0221; H05K 1/14; H05K 7/1427

(57) ABSTRACT

A circuit board assembly includes a casing, a first circuit board, a second circuit board, plural connectors and at least one fastening element. The casing includes plural openings and at least one first coupling part. The first circuit board includes at least one second coupling part. The second circuit board includes at least one conductive part. The plural connectors are partially penetrated through the corresponding openings and electrically connected with the second circuit board. The second circuit board is assembled with the casing through the plural connectors. The conductive part of the second circuit board is electrically connected with the first circuit board, and the second circuit board is perpendicular to the first circuit board. The first coupling part of the casing and the second coupling part of the first circuit board are connected with each other through the fastening element.

### FIELD OF THE INVENTION

The present invention relates to a circuit board assembly and an assembling method thereof, and more particularly to a circuit board assembly using a casing of an electronic device as an auxiliary supporting structure and an assembling method thereof.

### BACKGROUND OF THE INVENTION

With increasing development of electronic industries, the internal circuitries of electronic devices are gradually modularized. In other words, plural electronic components are integrated into a single functional module. Moreover, plural functional modules may be integrated with each other so as to increase the integration level and the functions of the electronic device.

Generally, these functional modules are mounted on daughter boards. After the daughter boards are installed on a system circuit board, these functional modules cooperate with each other to implement specified functions. Conventionally, there are several approaches for installing the daughter board onto a system circuit board. For example, by a pin-through-hole technology, plural conductive pins are firstly mounted on the daughter board, then inserted into predetermined holes of the system circuit board, and finally welded on the system circuit board through solder paste. Since the inner walls of these holes are coated with conductive material, the daughter board is electrically connected to and fixed on the system circuit board via these conductive pins. However, while the conductive pins are welded on the system circuit board through solder paste, an additional jig tool is required to assist in supporting the daughter board in order for allowing the daughter board to be perpendicular to the system circuit board and allowing the conductive pins to be electrically connected with the system circuit board.

Since the process of assembling the circuit board assembly needs the additional jig tool to assist in supporting the daughter board, the process complexity and the fabricating cost increase.

In addition, the conventional daughter board with integrated functional modules has plural connectors. The connectors of the daughter board are configured to connect with various expansion devices for expanding the functions of the daughter board. For making sure that the daughter board can be connected with various expansion devices, different type connectors may be collectively disposed on the daughter board. For example, two 4-pin connectors, two 6-pin connectors with and two 8-pin connectors are collectively disposed on the daughter board. Under this circumstance, the expandability of the daughter board is limited by the plural connectors. If the daughter board is required to be connected with one or more expansion devices with three 6-pin connectors, the connection between the daughter board and the expansion devices can't be performed. Consequently, the adaptability and expandability of the circuit board assembly is limited.

Therefore, there is a need of providing an improved circuit board assembly and an assembling method thereof in order to overcome the above drawbacks.

### SUMMARY OF THE INVENTION

An object of the present invention provides a circuit board assembly with strong structural strength and increased expansibility.

An object of the present invention provides an assembling method for assembling a circuit board assembly in a simplified manner and without using the additional jig tool, so that the assembling cost is reduced.

A further object of the present invention provides an assembling method for assembling a circuit board assembly. Firstly, a second circuit board is assembled with a casing. Then, the second circuit board is electrically connected with a first circuit board. Afterwards, the casing is fixed on the first circuit board, so that the second circuit board is supported by the casing. Consequently, the assembling method is simplified, time-saving and cost-effective, and the structural strength of the circuit board assembly is enhanced.

In accordance with an aspect of the present invention, there is provided a circuit board assembly of an electronic device. The circuit board assembly includes a casing, a first circuit board, a second circuit board, plural connectors and at least one fastening element. The casing includes plural openings and at least one first coupling part. The first circuit board includes at least one second coupling part. The second circuit board includes at least one conductive part. The plural connectors are partially penetrated through the corresponding openings of the casing and electrically connected with the second circuit board. The second circuit board is assembled with the casing through the plural connectors, and the second circuit board is in parallel with the casing. The at least one conductive part of the second circuit board is electrically connected with the first circuit board, and the second circuit board is perpendicular to the first circuit board. The at least one first coupling part of the casing and the at least one second coupling part of the first circuit board are connected with each other through the at least one fastening element.

In accordance with another aspect of the present invention, there is provided an assembling method of a circuit board assembly. The assembling method comprises the steps of: (a) providing a casing, a first circuit board, a second circuit board, plural connectors and at least one fastening element, wherein the casing comprises plural openings and at least one first coupling part, the first circuit board comprises at least one second coupling part, and the second circuit board comprises at least one conductive part; (b) connecting the plural connectors with the second circuit board and allowing the plural connectors to be penetrated through the corresponding openings of the casing, so that the second circuit board and the casing are combined together via the plural connectors, and the second circuit board is in parallel with the casing; (c) connecting the at least one conductive part of the second circuit board with the first circuit board, and allowing the second circuit board to be perpendicular to the first circuit board; (d) connecting the at least one first coupling part of the casing and the at least one second coupling part of the first circuit board together through the at least one fastening element, so that the casing is fixed on the first circuit board; and (e) performing a reflow soldering process to the casing, the first circuit board and the second circuit board, so that the circuit board assembly is assembled.

In accordance with a further aspect of the present invention, there is provided an assembling method of a circuit board assembly. The assembling method comprises the steps of: (a) providing a casing, a first circuit board, a second circuit board, plural connectors and at least one fastening element, wherein the casing comprises plural openings and at least one first coupling part, the first circuit board comprises at least one conductive structure and at least one second coupling part, and the second circuit board comprises at least one conductive part; (b) connecting the plural connectors with the second circuit board and allowing the plural connectors to be penetrated through the corresponding openings of the casing, so that the second circuit board and the casing are combined together via the plural connectors, and the second circuit board is in parallel with the casing; (c) connecting the at least one conductive part of the second circuit board with the at least one conductive structure of the first circuit board, and allowing the second circuit board to be perpendicular to the first circuit board; and (d) connecting the at least one first coupling part of the casing and the at least one second coupling part of the first circuit board together through the at least one fastening element, so that the casing is fixed on the first circuit board.

The above contents of the present invention will become more readily apparent to those ordinarily skilled in the art after reviewing the following detailed description and accompanying drawings, in which:

### BRIEF DESCRIPTION OF THE DRAWINGS

FIG. 1A is a schematic perspective view illustrating a circuit board assembly according to a first embodiment of the present invention;

FIG. 1B is a schematic perspective view illustrating the circuit board assembly of FIG. 1A and taken along another viewpoint;

FIG. 2 is a flowchart illustrating an assembling method for assembling the circuit board assembly of FIG. 1;

FIG. 3 is a schematic perspective view illustrating a circuit board assembly according to a second embodiment of the present invention;

FIG. 4 is a schematic perspective view illustrating a circuit board assembly according to a third embodiment of the present invention;

FIG. 5 is a flowchart illustrating an assembling method for assembling the circuit board assembly of FIG. 4;

FIG. 6 is a schematic perspective view illustrating a portion of a circuit board assembly according to a fourth embodiment of the present invention;

FIG. 7A is a schematic perspective view illustrating a portion of a circuit board assembly according to a fifth embodiment of the present invention; and

FIG. 7B is a schematic cross-sectional view illustrating the relationship between the connector and the casing of the circuit board assembly of FIG. 7A.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

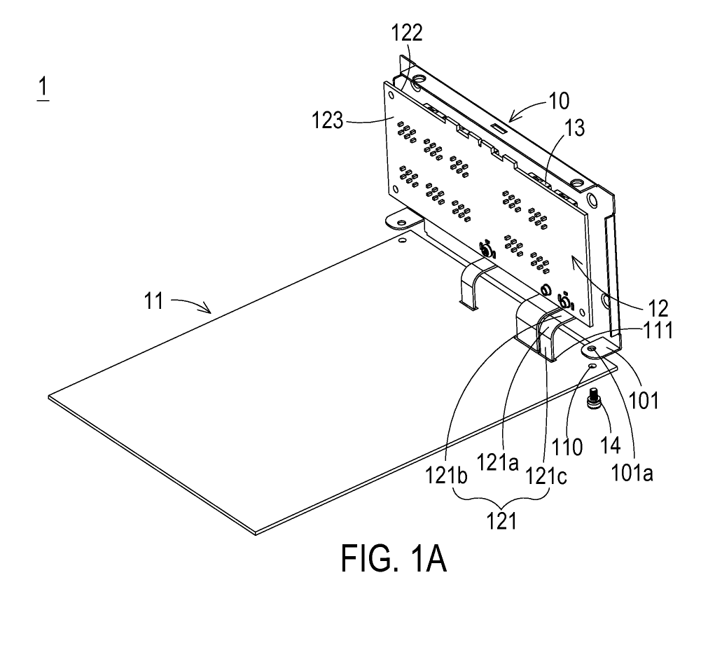

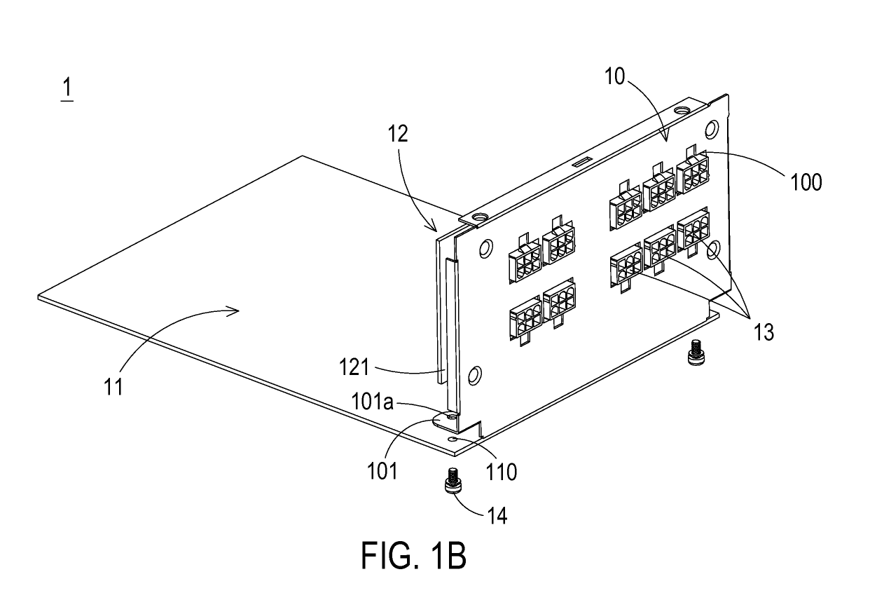

FIG. 1A is a schematic perspective view illustrating a circuit board assembly according to a first embodiment of the present invention. FIG. 1B is a schematic perspective view illustrating the circuit board assembly of FIG. 1A and taken along another viewpoint. The circuit board assembly 1 is applied to an electronic device (not shown). As shown in FIGS. 1A and 1B, the circuit board assembly 1 comprises a casing 10, a first circuit board 11, a second circuit board 12, plural connectors 13 and at least one fastening element 14. The casing 10 comprises plural openings 100 (see FIG. 1B) and at least one first coupling part 101. The first circuit board 11 comprises at least one second coupling part 110 corresponding to the at least one first coupling part 101 of the casing 10. The second circuit board 12 comprises at least one conductive part 121. The plural connectors 13 are electrically connected with the second circuit board 12. Moreover, the plural connectors 13 are penetrated through the corresponding openings 100 of the casing 10. Consequently, the second circuit board 12 and the casing 10 are combined together via the plural connectors 13, and the second circuit board 12 is in parallel with the casing 10. Moreover, the at least one conductive part 121 of the second circuit board 12 is electrically connected with the first circuit board 11. Consequently, the second circuit board 12 is perpendicular to the first circuit board 11. Moreover, the at least one first coupling part 101 of the casing 10 and the at least one second coupling part 110 of the first circuit board 11 are connected with each other through the corresponding fastening element 14.

Please refer to FIGS. 1A and 1B again. The second circuit board 12 has a first surface 122 and a second surface 123. The first surface 122 and the second surface 123 are opposed to each other. In this embodiment, the plural connectors 13 are disposed on the first surface 122 of the second circuit board 12 and electrically connected with the second circuit board 12. Preferably but not exclusively, the plural connectors 13 are the same type connectors. An example of each connector 13 includes but is not limited to a six pin connector. In this embodiment, the conductive part 121 of the second circuit board 12 is a metal slice. The conductive part 121 comprises a first end 121b, a second end 121c and a bent structure 121a. The first end 121b is fixed on the first surface 122 of the second circuit board 12. The bent structure 121a is arranged between the first end 121b and the second end 121c. The second end 121c is inserted into a corresponding insertion slot 111 of the first circuit board 11. Due to the bent structure 121a, the second circuit board 12 can be perpendicular to the first circuit board 11.

Preferably but not exclusively, the casing 10 is made of a metallic material. In an embodiment, the first coupling part 101 of the casing 10 is a bent plate, which is protruded from a bottom edge of the casing 10. Moreover, the first coupling part 101 of the casing 10 has a perforation 101a. In an embodiment, the second coupling part 110 of the first circuit board 11 is a fixing hole of the first circuit board 11. For assembling the casing 10 with the first circuit board 11, the first coupling part 101 is disposed on the first circuit board 11, and the perforation 101a of the first coupling part 101 is aligned with the fixing hole (i.e. the second coupling part 110) of the first circuit board 11. An example of the fastening element 14 includes but is not limited to a screw. After the fastening element 14 is tightened into the perforation 101a of the first coupling part 101 and the fixing hole of the first circuit board 11, the casing 10 and the first circuit board 11 are combined together. As long as the casing 10 and the first circuit board 11 are combined together through the at least one first coupling part 101 of the casing 10 and the at least one second coupling part 110 of the first circuit board 11, the number of the first coupling parts 101 and the number of the second coupling part 110 may be varied according to the practical requirements.

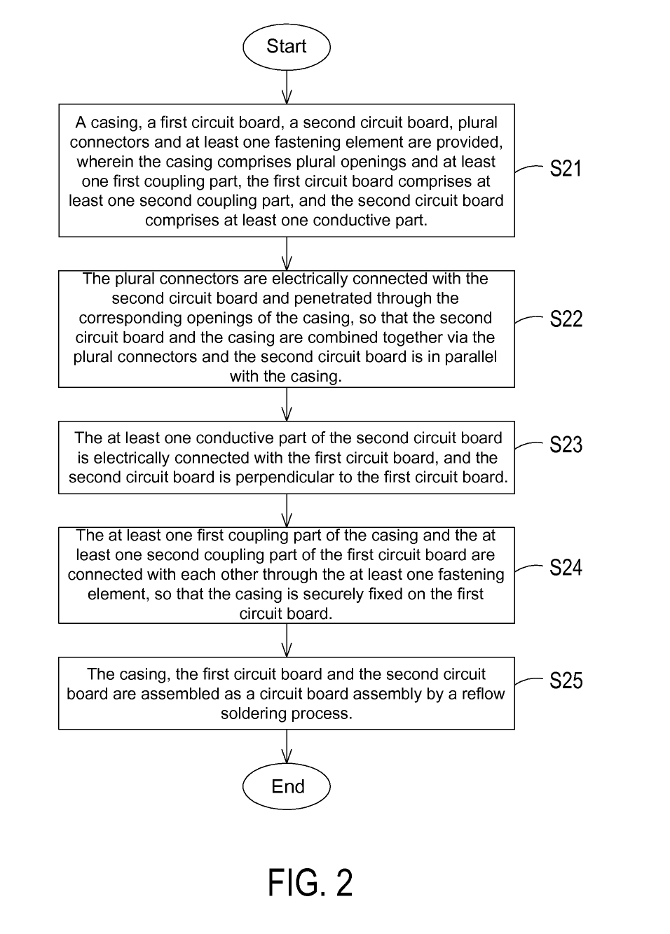

FIG. 2 is a flowchart illustrating an assembling method for assembling the circuit board assembly of FIG. 1. Please refer to FIGS. 1A, 1B and 2. Firstly, in a step S21, a casing 10, a first circuit board 11, a second circuit board 12, plural connectors 13 and plural fastening elements 14 are provided. The casing 10 comprises plural openings 100 and at least one first coupling part 101. The first circuit board 11 comprises at least one second coupling part 110. The second circuit board 12 comprises at least one conductive part 121. Then, in a step S22, the plural connectors 13 are electrically connected with the second circuit board 12. In an embodiment, the plural connectors 13 are firstly welded on a first surface 122 of the second circuit board 12. In another embodiment, the plural connectors 13 are detachably connected with the second circuit board 12. Moreover, the plural connectors 13 are penetrated through the corresponding openings 100 of the casing 10, so that the second circuit board 12 and the casing 10 are combined together via the plural connectors 13. The second circuit board 12 is in parallel with the casing 10. Then, in a step S23, the at least one conductive part 121 of the second circuit board 12 is electrically connected with the first circuit board 11, and the second circuit board 12 is perpendicular to the first circuit board 11. Then, in a step S24, the at least one first coupling part 101 of the casing 10 and the at least one second coupling part 110 of the first circuit board 11 are connected with each other through the at least one fastening element 14. Consequently, the casing 10 is securely fixed on the first circuit board 11. Moreover, since the casing 10 is fixed on the first circuit board 11, the second circuit board 12 can be connected with the first circuit board 11 more securely. Then, in a step S25, the casing 10, the first circuit board 11 and the second circuit board 12 are assembled as the circuit board assembly 1 by a reflow soldering process.

From the above descriptions, the casing 10 is used as an auxiliary supporting structure for assisting in supporting the second circuit board 12. By means of the casing 10, the second circuit board 12 can be securely fixed on the first circuit board 11, and the structural strength of the circuit board assembly 1 is enhanced. Under this circumstance, it is not necessary to use an additional jig tool to support the second circuit board 12.

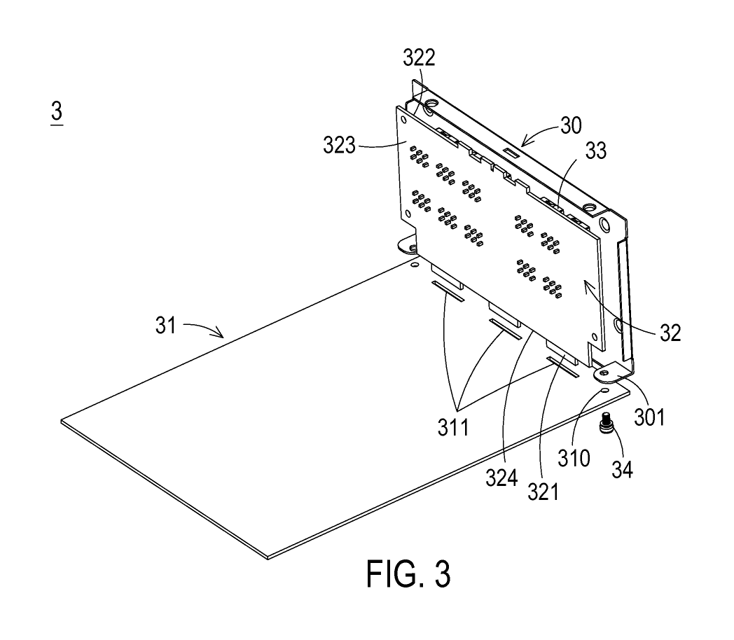

FIG. 3 is a schematic perspective view illustrating a circuit board assembly according to a second embodiment of the present invention. The circuit board assembly 3 is applied to an electronic device (not shown). As shown in FIG. 3, the circuit board assembly 3 comprises a casing 30, a first circuit board 31, a second circuit board 32, plural connectors 33 and at least one fastening element 34. The casing 30 comprises plural openings (not shown) and at least one first coupling part 301. The first circuit board 31 comprises at least one second coupling part 310. The second circuit board 32 comprises at least one conductive part 321. The plural connectors 33 are electrically connected with the second circuit board 32. Moreover, the plural connectors 33 are penetrated through the corresponding openings of the casing 30. The connecting relationships between the casing 30, the first circuit board 31, the second circuit board 32, the plural connectors 33 and the at least one fastening element 34 are similar to those of the first embodiment, and are not redundantly described herein. In comparison with the first embodiment, the at least one conductive part 321 of the second circuit board 32 is distinguished.

As shown in FIG. 3, the second circuit board 32 comprises a first surface 322, a second surface 323 and a bottom edge 324. The first surface 322 and the second surface 323 are opposed to each other. The bottom edge 324 is connected with the first surface 322 and the second surface 323. In this embodiment, the conductive part 321 of the second circuit board 32 is a metal pin, which is protruded downwardly from the bottom edge 324 of the second circuit board 32. Moreover, the first circuit board 31 comprises at least one insertion slot 311 corresponding to the at least one metal pin (i.e. the conductive part 321). For assembling the second circuit board 32 with the first circuit board 31, the at least one conductive part 321 of the second circuit board 32 is inserted into the at least one insertion slot 311 of the first circuit board 31. Consequently, the second circuit board 32 is perpendicular to the first circuit board 31 and electrically connected with the first circuit board 31. The assembling method of the circuit board assembly 3 is similar to the assembling method of the circuit board assembly 1 of the first embodiment, and is not redundantly described herein.

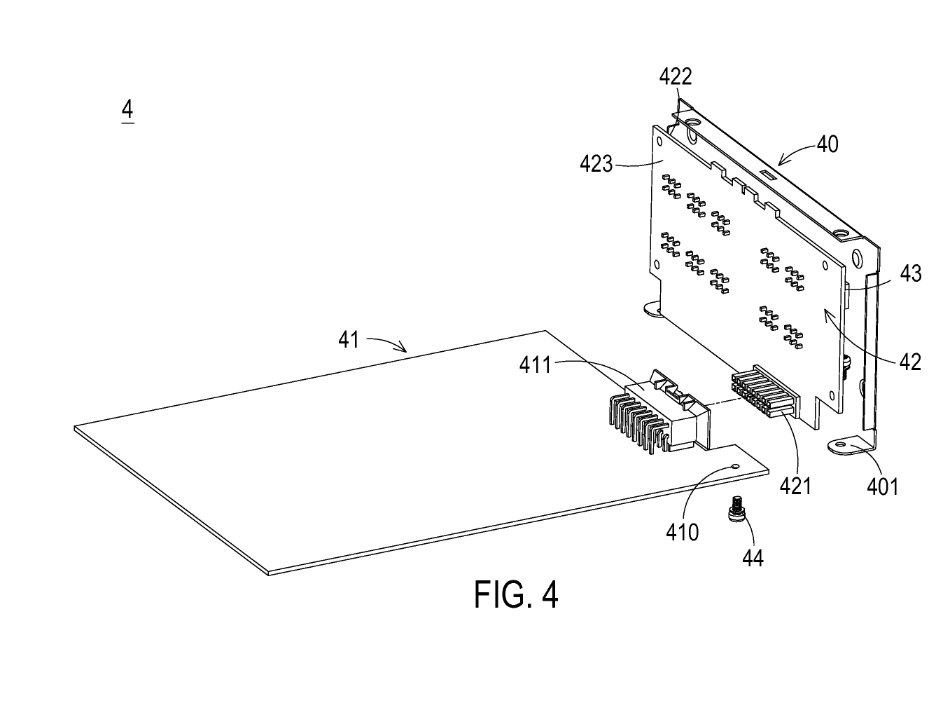

FIG. 4 is a schematic perspective view illustrating a circuit board assembly according to a third embodiment of the present invention. The circuit board assembly 4 is applied to an electronic device (not shown). As shown in FIG. 4, the circuit board assembly 4 comprises a casing 40, a first circuit board 41, a second circuit board 42, plural connectors 43 and at least one fastening element 44. The casing 40 comprises plural openings (not shown) and at least one first coupling part 401. The first circuit board 41 comprises at least one second coupling part 410. The second circuit board 42 comprises at least one conductive part 421. The connecting relationships between the casing 40, the first circuit board 41, the second circuit board 42, the plural connectors 43 and the at least one fastening element 44 are similar to those of the above embodiments, and are not redundantly described herein. In comparison with the above embodiments, the at least one conductive part 421 of the second circuit board 42 is distinguished.

As shown in FIG. 4, the second circuit board 42 has a first surface 422 and a second surface 423. The first surface 422 and the second surface 423 are opposed to each other. In this embodiment, the plural connectors 43 are disposed on the first surface 422 of the second circuit board 42 and electrically connected with the second circuit board 42. In this embodiment, the plural connectors 43 are the same type connectors. An example of each connector 43 includes but is not limited to a six pin connector. The plural connectors 43 may be coupled with the corresponding connectors (not shown) of the electronic device. In this embodiment, the conductive part 421 of the second circuit board 42 is disposed on the second surface 423 of the second circuit board 42 and located near a bottom of the second surface 423. Moreover, a conductive structure 411 is disposed on the first circuit board 41 and at the location corresponding to the conductive part 421 of the second circuit board 42. In this embodiment, the conductive part 421 of the second circuit board 42 is a male connector, and the conductive structure 411 of the first circuit board 41 is a female connector. The conductive part 421 and the conductive structure 411 are connected with each other. Consequently, the second circuit board 42 is perpendicular to the first circuit board 41 and electrically connected with the first circuit board 41. It is noted that the types of the conductive part 421 and the conductive structure 411 are not restricted. For example, in another embodiment, the conductive part 421 of the second circuit board 42 is a female connector, and the conductive structure 411 of the first circuit board 41 is a male connector. Moreover, the conductive part 421 of the second circuit board 42 and the conductive structure 411 of the first circuit board 41 may be arranged in a horizontal form or a vertical form. Regardless of the structures of the conductive part 421 and the conductive structure 411, the second circuit board 42 is perpendicular to the first circuit board 41 and electrically connected with the first circuit board 41.

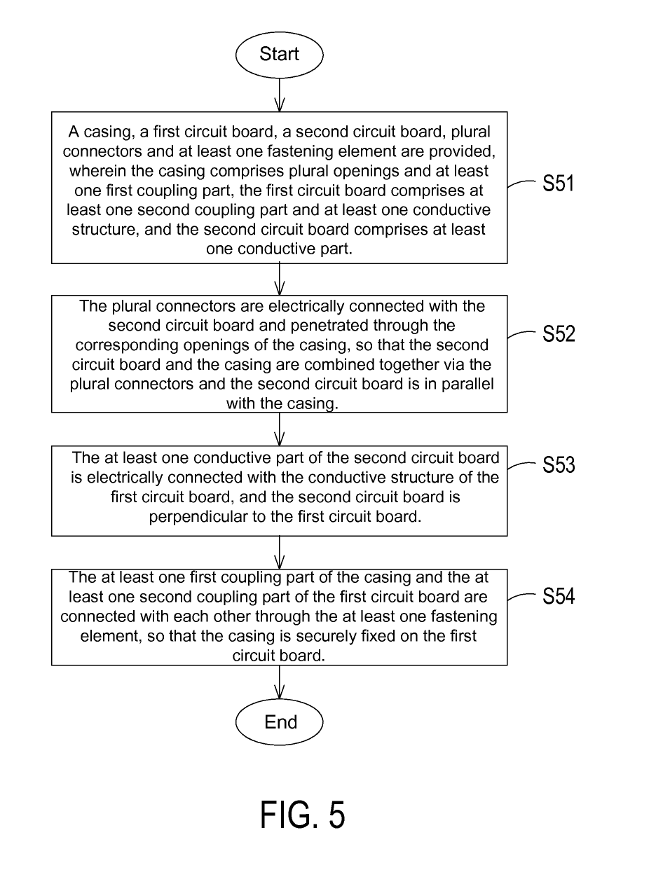

FIG. 5 is a flowchart illustrating an assembling method for assembling the circuit board assembly of FIG. 4. Firstly, in a step S51, a casing 40, a first circuit board 41, a second circuit board 42, plural connectors 43 and plural fastening elements 44 are provided. The casing 40 comprises plural openings (not shown) and at least one first coupling part 401. The first circuit board 41 comprises at least one second coupling part 410 and at least one conductive structure 411. The second circuit board 42 comprises at least one conductive part 421. In this embodiment, the conductive part 421 of the second circuit board 42 is a male connector, and the conductive structure 411 of the first circuit board 41 is a female connector. Alternatively, in some other embodiments, the conductive part 421 of the second circuit board 42 is a female connector, and the conductive structure 411 of the first circuit board 41 is a male connector. Moreover, in the step S51, at least one conductive structure 411 is mounted on the first circuit board 41 and the at least one conductive part 421 is mounted on the second circuit board 42 by a reflow soldering process. Then, in a step S52, the plural connectors 43 are electrically connected with the second circuit board 42. Moreover, the plural connectors 43 are penetrated through the corresponding openings of the casing 40, so that the second circuit board 42 and the casing 40 are combined together via the plural connectors 43. The second circuit board 42 is in parallel with the casing 40.

Then, in a step S53, the at least one conductive part 421 of the second circuit board 42 is connected with the conductive structure 411 of the first circuit board 41. Consequently, the second circuit board 42 is perpendicular to the first circuit board 41 and electrically connected with the first circuit board 41. Then, in a step S54, the at least one first coupling part 401 of the casing 40 and the at least one second coupling part 410 of the first circuit board 41 are connected with each other through the at least one fastening element 44. Consequently, the casing 40 is securely fixed on the first circuit board 41. Moreover, since the casing 40 is fixed on the first circuit board 41, the second circuit board 42 can be connected with the first circuit board 41 more securely.

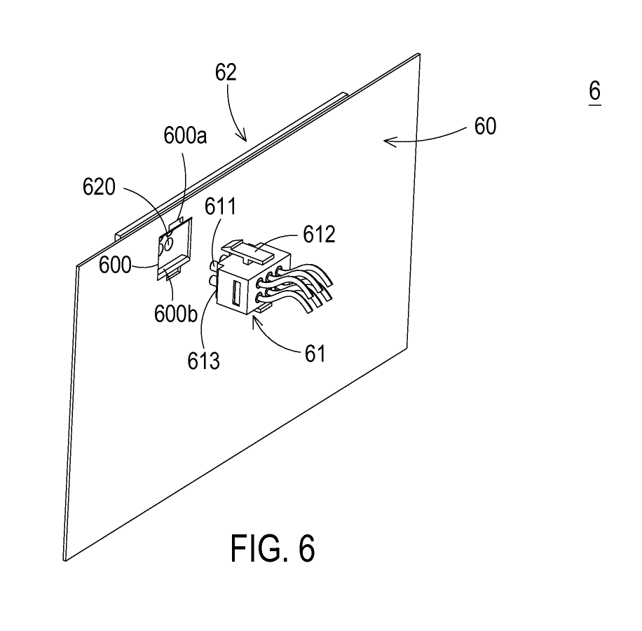

FIG. 6 is a schematic perspective view illustrating a portion of a circuit board assembly according to a fourth embodiment of the present invention. The circuit board assembly 6 is applied to an electronic device (not shown). As shown in FIG. 6, the circuit board assembly 6 comprises a casing 60, a first circuit board (not shown), a second circuit board 62, plural connectors 61 and at least one fastening element (not shown). The connecting relationship between the casing 60 and the first circuit board is similar to that of the first embodiment, and is not redundantly described herein. In this embodiment, the connectors 61 are detachably connected with the second circuit board 62. As shown in FIG. 6, the connector 61 comprises plural conducting posts 611, and the second circuit board 62 comprises plural contact pads 620 corresponding to the conducting posts 611. The plural conducting posts 611 are contacted with the corresponding contact pads 620, so that the connector 61 is electrically connected with the second circuit board 62. Moreover, the connector 61 further comprises two magnetic elements 613. The two magnetic elements 613 are disposed on two lateral ends of the connector 61 and face the casing 60. When the connectors 61 are penetrated through the corresponding openings 600 of the casing 60, the magnetic elements 613 are magnetically attached on the casing 60, which is made of the metallic material. Consequently, the connectors 61 are connected with the casing 60. Under this circumstance, the plural conducting posts 611 of the connectors 61 are contacted with the corresponding contact pads 620 of the second circuit board 62, so that the connector 61 is electrically connected with the second circuit board 62. Since the casing 60 is used as an auxiliary supporting structure for assisting in supporting the second circuit board 62, the second circuit board 62 is in parallel with the casing 60.

Please refer to FIG. 6 again. For facilitating fixing the connector 61 on the casing 60, the connector 61 further comprises at least one locking part 612. In this embodiment, the connector 61 comprises two locking parts 612. The two locking parts 612 are disposed on a top surface and a bottom surface of the connector 61, respectively. It is noted that the number and the location of the at least one locking part 612 are not restricted. Moreover, the casing 60 further comprises two locking slots 600a corresponding to the two locking parts 612 of the connector 61. That is, the two locking slots 600a are located at a top edge and a bottom edge of the opening 600. When the connector 61 is penetrated through the corresponding opening 600 of the casing 60, the locking parts 612 of the connector 61 are inserted into the corresponding locking slots 600a of the casing 60 and contacted with the inner surface of the casing 60. Consequently, the connector 61 can be securely fixed on the casing 60. Moreover, the casing 60 further comprises a guiding part 600b. The guiding part 600b is protruded from the inner surface of the casing 60 and near a periphery of the opening 600. While the connector 61 is penetrated through the corresponding opening 600 of the casing 60, the connector 61 is guided by the guiding part 600b of the casing 60 so as to be smoothly introduced into the opening 600. In other words, the guiding part 600b can assist in positioning the connector 61 in the opening 600.

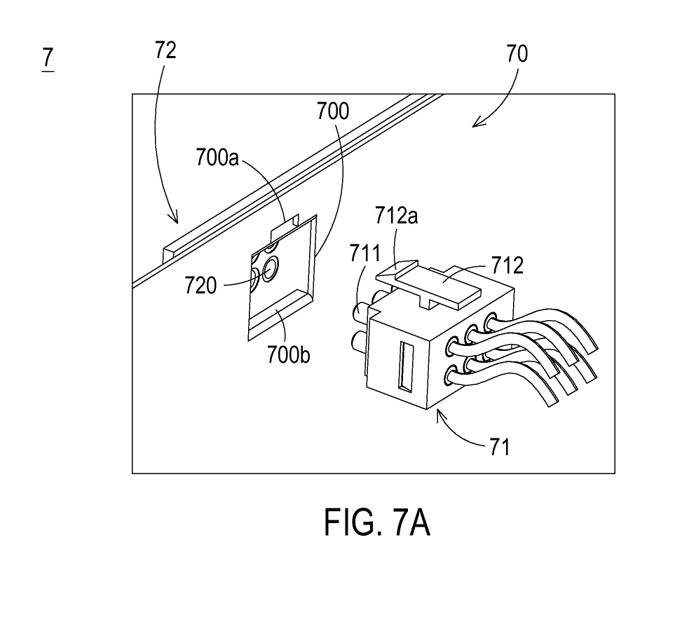

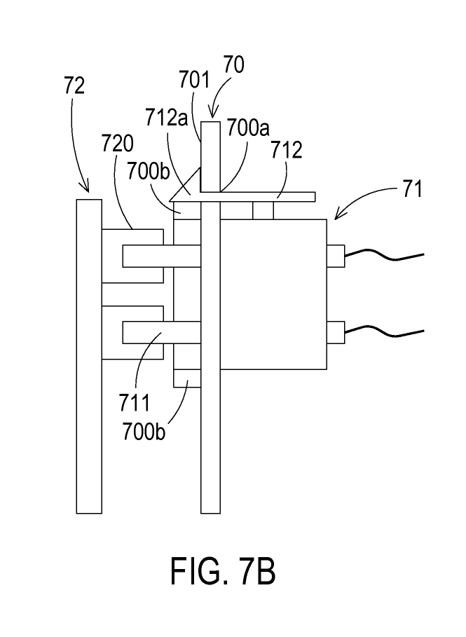

FIG. 7A is a schematic perspective view illustrating a portion of a circuit board assembly according to a fifth embodiment of the present invention. FIG. 7B is a schematic cross-sectional view illustrating the relationship between the connector and the casing of the circuit board assembly of FIG. 7A. The circuit board assembly 7 is applied to an electronic device (not shown). The circuit board assembly 7 comprises a casing 70, a first circuit board (not shown), a second circuit board 72, plural connectors 71 and at least one fastening element (not shown). The connecting relationship between the casing 70 and the first circuit board is similar to that of the first embodiment, and is not redundantly described herein. In this embodiment, the connectors 71 are detachably connected with the second circuit board 72. The connector 71 comprises plural conducting posts 711, and the second circuit board 72 comprises plural hollow pins 720 corresponding to the conducting posts 711. The plural conducting posts 711 are contacted with the corresponding hollow pins 720, so that the connector 71 is electrically connected with the second circuit board 72.

For facilitating fixing the connector 71 on the casing 70, the connector 71 further comprises at least one locking part 712. In this embodiment, the connector 71 comprises one locking part 712. The locking part 712 is disposed on a top surface of the connector 71. Moreover, the locking part 712 comprises a hook structure 712a. The hook structure 712a is located at a front end of the locking part 712. Moreover, the casing 70 further comprises a locking slot 700a corresponding to the locking part 712 of the connector 71. That is, the locking slot 700a is located at a top edge of the opening 700. When the connector 71 is penetrated through the corresponding opening 700 of the casing 70, the locking part 712 of the connector 71 is penetrated through the locking slot 700a of the casing 70 and the hook structure 712a is contacted with an inner surface 701 of the casing 70. Consequently, the connector 71 can be securely fixed on the casing 70. Moreover, the casing 70 further comprises a guiding part 700b. The guiding part 700b is protruded from the inner surface of the casing 70 and near a periphery of the opening 700. For example, the guiding part 700b is located near a top periphery and a bottom periphery of the opening 700. While the connector 71 is penetrated through the corresponding opening 700 of the casing 70, the connector 71 is guided by the guiding part 700b of the casing 70 so as to be smoothly introduced into the opening 700. In other words, the guiding part 700b can assist in positioning the connector 71 in the opening 700.

From the above descriptions, the present invention provides a circuit board assembly and an assembling method thereof. The circuit board assembly comprises a casing, a first circuit board, a second circuit board, plural connectors and at least one fastening element. The plural connectors are the same type connectors. Firstly, the second circuit board is assembled with the casing through the plural connectors, wherein the second circuit board is in parallel with the casing. Then, the second circuit board is electrically connected with the first circuit board, wherein the second circuit board is perpendicular to the first circuit board. The casing and the first circuit board are connected with each other through the at least one fastening element. Afterwards, the casing, the first circuit board and the second circuit board are combined together by a reflow soldering process. Since the casing is used as an auxiliary supporting structure for assisting in supporting the second circuit board, it is not necessary to use an additional jig tool to support the second circuit board during the reflow soldering process. Consequently, the assembling method of the present invention is simplified, time-saving and cost-effective, and the structural strength of the circuit board assembly is enhanced. In addition, the plural connectors are the same type connectors. The adaptability and expandability of the circuit board assembly is enhanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A circuit board assembly of an electronic device, the circuit board assembly comprising:
a casing comprising plural openings and at least one first coupling part;
a first circuit board comprising at least one second coupling part;
a second circuit board comprising at least one conductive part;
plural connectors partially penetrated through the corresponding openings of the casing and electrically connected with the second circuit board, wherein the second circuit board is assembled with the casing through the plural connectors, and the second circuit board is in parallel with the casing; and
at least one fastening element,
wherein the at least one conductive part of the second circuit board is electrically connected with the first circuit board, and the second circuit board is perpendicular to the first circuit board, wherein the at least one first coupling part of the casing and the at least one second coupling part of the first circuit board are connected with each other through the at least one fastening element.

2. The circuit board assembly according to claim 1, wherein the second circuit board has a first surface, and the plural connectors are disposed on the first surface of the second circuit board and electrically connected with the second circuit board, wherein the plural connectors are same type connectors.

3. The circuit board assembly according to claim 1, wherein the conductive part of the second circuit board is a metal slice with a first end, a second end and a bent structure, wherein the first end of the metal slice is fixed on a first surface of the second circuit board, the bent structure is arranged between the first end and the second end of the metal slice, and the second end of the metal slice is inserted into a corresponding insertion slot of first circuit board, so that the second circuit board is perpendicular to and electrically connected with the first circuit board.

4. The circuit board assembly according to claim 1, wherein the second circuit board has a first surface and a second surface opposed to the first surface, and a conductive structure is disposed on the first circuit board, wherein the plural connectors are disposed on the first surface of the second circuit board, the conductive part is disposed on the second surface of the second circuit board and located near a bottom of the second surface, and the conductive part of the second circuit board is connected with the conductive structure of the first circuit board, so that the second circuit board is perpendicular to and electrically connected with the first circuit board.

5. The circuit board assembly according to claim 1, wherein the conductive part of the second circuit board is a metal pin, and the metal pin is protruded downwardly from a bottom edge of the second circuit board, wherein the first circuit board comprises at least one insertion slot, and the at least one conductive part is inserted into the at least one insertion slot, so that the second circuit board is perpendicular to and electrically connected with the first circuit board.

6. The circuit board assembly according to claim 1, wherein each of the plural connectors comprises plural conducting posts and at least one magnetic element, and the second circuit board comprises plural contact pads corresponding to the conducting posts, wherein after the connector is penetrated through the corresponding opening of the casing, the conducting posts are contacted with the corresponding contact pads and the magnetic element is magnetically attached on the casing, so that the connector is fixed on the casing.

7. The circuit board assembly according to claim 1, wherein each of the plural connector comprises plural conducting posts, and the second circuit board comprises plural hollow pins corresponding to the conducting posts, wherein after the plural conducting posts are contacted with the corresponding hollow pins, the connector is electrically connected with the second circuit board.

8. The circuit board assembly according to claim 1, wherein each of the plural connectors further comprises at least one locking part, and the casing further comprises at least one locking slot corresponding to the at least one locking part, wherein while the connector is penetrated through the corresponding opening of the casing, the locking part is inserted into corresponding locking slot and contacted with a surface of the casing, so that the connector is fixed on the casing.

9. The circuit board assembly according to claim 1, wherein the casing further comprises a guiding part, and the guiding part is protruded from a surface of the casing and near a periphery of the corresponding opening, wherein while the connector is penetrated through the corresponding opening of the casing, the connector is guided by the guiding part of the casing so as to be smoothly introduced into the opening.

10. An assembling method of a circuit board assembly, comprising:
(a) providing a casing, a first circuit board, a second circuit board, plural connectors and at least one fastening element, wherein the casing comprises plural openings and at least one first coupling part, the first circuit board comprises at least one second coupling part, and the second circuit board comprises at least one conductive part;
(b) connecting the plural connectors with the second circuit board and allowing the plural connectors to be penetrated through the corresponding openings of the casing, so that the second circuit board and the casing are combined together via the plural connectors, and the second circuit board is in parallel with the casing;
(c) connecting the at least one conductive part of the second circuit board with the first circuit board, and allowing the second circuit board to be perpendicular to the first circuit board;
(d) connecting the at least one first coupling part of the casing and the at least one second coupling part of the first circuit board together through the at least one fastening element, so that the casing is fixed on the first circuit board; and
(e) performing a reflow soldering process to the casing, the first circuit board and the second circuit board, so that the circuit board assembly is assembled.

11. The assembling method according to claim 10, wherein in the step (a), the second circuit board has a first surface, wherein in the step (b), the plural connectors are disposed on the first surface of the second circuit board and electrically connected with the second circuit board, wherein the plural connectors are same type connectors.

12. The assembling method according to claim 10, wherein in the step (a), the conductive part of the second circuit board is a metal slice with a first end, a second end and a bent structure, wherein the first end of the metal slice is fixed on a first surface of the second circuit board, and the bent structure is arranged between the first end and the second end of the metal slice, wherein in the step (c), the second end of the metal slice is inserted into a corresponding insertion slot of first circuit board, so that the second circuit board is perpendicular to and electrically connected with the first circuit board.

13. The assembling method according to claim 10, wherein in the step (a), the conductive part of the second circuit board is a metal pin, and the metal pin is protruded downwardly from a bottom edge of the second circuit board, wherein the first circuit board comprises at least one insertion slot, wherein in the step (c), the at least one conductive part is inserted into the at least one insertion slot, so that the second circuit board is perpendicular to and electrically connected with the first circuit board.

14. The assembling method according to claim 1, wherein in the step (a), each of the plural connectors comprises plural conducting posts and at least one magnetic element, wherein in the step (b), the second circuit board comprises plural contact pads corresponding to the conducting posts, wherein after the connector is penetrated through the corresponding opening of the casing, the conducting posts are contacted with the corresponding contact pads and the magnetic element is magnetically attached on the casing, so that the connector is fixed on the casing.

15. The assembling method according to claim 10, wherein in the step (a), each of the plural connector comprises plural conducting posts, wherein in the step (b), the second circuit board comprises plural hollow pins corresponding to the conducting posts, wherein after the plural conducting posts are contacted with the corresponding hollow pins, the connector is electrically connected with the second circuit board.

16. The assembling method according to claim 10, wherein in the step (a), each of the plural connectors further comprises at least one locking part, and the casing further comprises at least one locking slot corresponding to the at least one locking part, wherein in the step (b), while the connector is penetrated through the corresponding opening of the casing, the locking part is inserted into corresponding locking slot and contacted with a surface of the casing, so that the connector is fixed on the casing.

17. The assembling method according to claim 10, wherein in the step (a), the casing further comprises a guiding part, and the guiding part is protruded from a surface of the casing and near a periphery of the corresponding opening, wherein in the step (b), while the connector is penetrated through the corresponding opening of the casing, the connector is guided by the guiding part of the casing so as to be smoothly introduced into the opening.

18. An assembling method of a circuit board assembly, comprising:
(a) providing a casing, a first circuit board, a second circuit board, plural connectors and at least one fastening element, wherein the casing comprises plural openings and at least one first coupling part, the first circuit board comprises at least one conductive structure and at least one second coupling part, and the second circuit board comprises at least one conductive part;
(b) connecting the plural connectors with the second circuit board and allowing the plural connectors to be penetrated through the corresponding openings of the casing, so that the second circuit board and the casing are combined together via the plural connectors, and the second circuit board is in parallel with the casing;
(c) connecting the at least one conductive part of the second circuit board with the at least one conductive structure of the first circuit board, and allowing the second circuit board to be perpendicular to the first circuit board; and
(d) connecting the at least one first coupling part of the casing and the at least one second coupling part of the first circuit board together through the at least one fastening element, so that the casing is fixed on the first circuit board.

19. The assembling method according to claim 18, wherein in the step (a), the second circuit board has a first surface, wherein in the step (b), the plural connectors are disposed on the first surface of the second circuit board and electrically connected with the second circuit board, wherein the plural connectors are same type connectors.

20. The assembling method according to claim 18, wherein in the step (a), the conductive structure of the first circuit board is a female connector and the conductive part of the second circuit board is a male connector, or the conductive structure of the first circuit board is a male connector and the conductive part of the second circuit board is a female connector, wherein in the step (a), the at least one conductive structure is mounted on the first circuit board and the at least one conductive part is mounted on the second circuit board by a reflow soldering process, wherein in the step (c), the at least one conductive part of the second circuit board is connected with the at least one conductive structure of the first circuit board, so that the second circuit board is perpendicular to the first circuit board and electrically connected with the first circuit board.
